(19) United States
(12) Patent Application Publication
(10) Pub. No.: US 2008/0285237 A1
(43) Pub. Date: Nov. 20, 2008

(54) Finned Heat Sink, Particularly for a Thermoelectric Module

(75) Inventors: Giorgio Pastorino, Lecco (IT); Roberto Carpentieri, Bergamo (IT)

Correspondence Address: LUCAS & MERCANTI, LLP, 475 PARK AVENUE SOUTH, 15TH FLOOR, NEW YORK, NY, 10016, US

(73) Assignee: PELTECH S.R.L., Calolziocorte (Lecco) (IT)

(21) Appl. No.: 12/094,835

(22) PCT Filed: Nov. 13, 2006
(86) PCT No.: PCT/IT06/00789

§ 371 Date: May 23, 2008

(30) Foreign Application Priority Data
Nov. 24, 2005 (IT) MI2005 U 000405

(51) Int. Cl. H05K 7/20

(52) U.S. Cl. 361/710

(57) ABSTRACT

The heat sink, particularly for a thermoelectric module, is of the kind formed of a plurality of first fin plates and second spacer plates, alternately disposed side by side and in contact with one another, and comprises fastening members which extend through the first and second plates for fastening one to the other. Each of said first and second plates has on one side at least a protrusion and on the opposite side at least a recess. The protrusion on one side of said first and second plates engages into the recess on a facing side of said second and first plates, respectively, with a positive fit. The protrusion on one side and the recess on the opposite side of said first and second plates are disposed out of alignment relative to a straight line on the plane of the plates intersecting the axis of the fastening members.

### TECHNICAL FIELD

The present invention relates to a finned heat sink, particularly for a thermoelectric module.

### BACKGROUND ART

A thermoelectric module essentially consists in a solid state device operating as a heat pump on the basis of the Peltier effect. A thermoelectric module typically comprises a plurality of pairs of elements made of semiconductor material of p and n type, the so called “thermoelectric elements”, which are connected electrically in series and thermically in parallel and arranged between two plates of ceramic material serving as a substrate for the thermoelectric elements. When an electric current is passed through the thermoelectric elements, heat is transferred from one side to the other of the thermoelectric module where it is removed by a heat sink. Generally, the heat sink is of the air cooled type and has a finned construction.

Various methods are known in the art for making a heat sink having a finned structure. The main known methods are described in the following.

According to a first known method, the finning of the heat sink is obtained by extrusion from a single piece of material and is made integrally with a base portion of the heat sink which has a flat surface intended to be connected to the hot side of the thermoelectric module, i.e. the side from which heat has to be removed. This method of manufacturing the heat sink has a low cost, but has a limit in that it is difficult to make a great number of long fins with narrow gaps between them.

In a second known method, the finning of the heat sink is made from a base portion of the heat sink having a flat surface intended to be connected to the hot side of the thermoelectric module and a series of grooves having a shape so that the fins can be inserted therein by applying a pressure, thus forming a group of parallel fins. This method of manufacturing the heat sink has a high cost because of the difficulty of assembling a great number of fins separated by a small gap on the base portion and because of the need to have recourse mainly to hand manufacturing for connecting the fins to the base portion of the heat sink, which connection has to be made by an interference fit in order to achieve a good contact between the base and the fins.

In a third known method the finning is made by machine working. This method has a high cost, also because of the machine tools required for machining, and does not lend itself to the production of a large number of pieces.

The drawback represented by the limits of the methods for making heat sinks having a finned structure described above is obviated by a fourth known method, according to which the heat sink is made by alternately disposing a first plate functioning as fin and a second plate functioning as spacer side by side and in contact with one another, so to form a base portion with a flat surface intended to be connected to the hot side of the thermoelectric module and series of parallel fins separated by a small gap. The base portion of the heat sink is held together by fastening members extending through the first and second plates in order to fasten one to the other. This method of construction of the heat sink has a lower cost than the foregoing methods described, also because it can be carried out easily by automatic operation. However, the heat sink thus made has the drawback that the fastening members securing the first and second plates do not ensure an adequate mechanical stability of the heat sink, therefore the first and second plates tend to rotate one relative to the other in their plane when assembling the heat sink, with the effect that the flat configuration of the surface of the base portion of the heat sink intended to be connected to the hot side of the thermoelectric module is deformed. Consequently heat transfer between the hot side of the thermoelectric module and the base portion of the heat sink is reduced because of an increase in the thermal resistance.

The technical problem underlying the present invention is, therefore, to improve the mechanical stability of a heat sink, particularly for a thermoelectric module, of the kind formed of a plurality of first fin plates and second spacer plates alternately disposed side by side and in contact with one another, and comprising fastening members which extend through the first and second plates for fastening one to the other, which in assembling is ensured against a relative rotation of said first and second plates in their plane and, therefore, against a deformation of the flat surface of the base portion of the heat sink intended to be connected to the hot side of the thermoelectric module.

### DISCLOSURE OF THE INVENTION

A solution to this technical problem is provided by a heat sink of the kind described above, wherein each of said first and second plates has on one side at least a protrusion and on the opposite side at least a recess, the protrusion on one side of said first and second plates engaging into the recess on the facing side of said second and first plates, respectively, with a positive fit, and the protrusion on the one side and the recess on the other side of said first and second plates are disposed cut of alignment relative to a straight line on the plane of the plates intersecting the axis of the fastening members.

### BRIEF DESCRIPTION OF THE DRAWINGS

The present invention will be described in more detail with reference to the accompanying illustrative drawings, of which:

FIG. 1 is a front elevational view of the heat sink according to the invention,

FIG. 2 is a side elevational view thereof,

FIG. 3 is a top view thereof,

FIG. 4 is a front elevational view of a spacer in the heat sink according to the invention,

FIG. 5 is a sectional view of the spacer in FIG. 4 taken along line V-V,

FIG. 6 is a front elevational view of a variant of the fin in the heat sink according to the invention,

FIG. 7 is a sectional view of the fin in FIG. 6 taken along line VII-VII, and

FIG. 8 is an enlarged view of a portion of the section of the fin in FIG. 7.

### BEST MODE FOR CARRYING OUT THE INVENTION

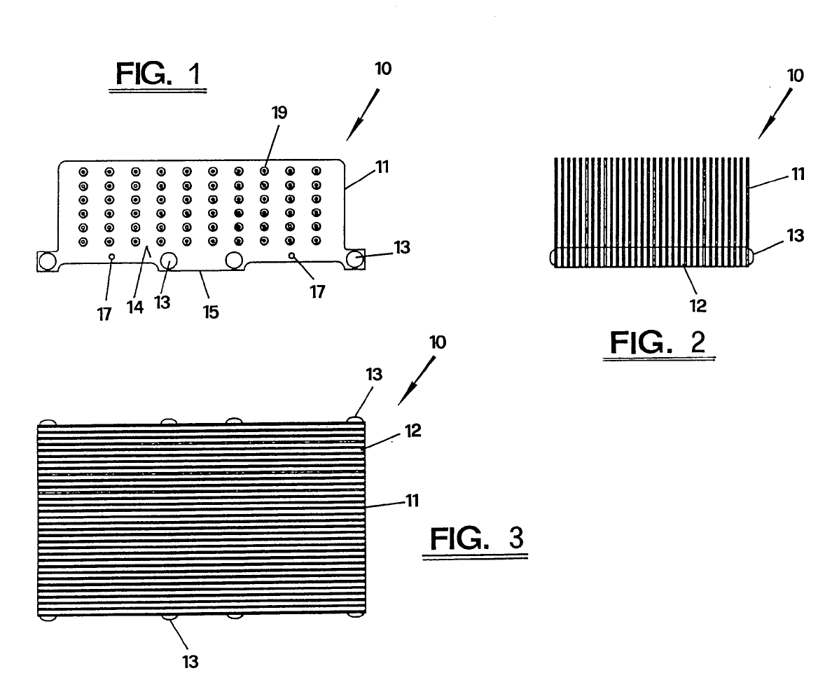

Referring to FIGS. 1 to 3 of the drawings, there is shown a heat sink according to the present invention, generally designated by 10. The heat sink is of the kind formed of a plurality of first fin plates 11 and second spacer plates 12 which first and second plates are alternately disposed side by side and in contact with one another, and are held together by fasteners 13 extending the entire length of the heat sink through suitable holes provided in said first and second plates. The fasteners 13 are formed, e.g., of elongated rivet or threaded members of conventional kind.

The heat sink 10 exhibits a base portion 14 having a fiat surface 15 intended to be connected to the hot side of a thermoelectric module (not shown), i.e. the side of the thermoelectric module from which heat has to be removed.

FIGS. 4 and 5 show a second spacer plate 12 of the heat sink. This plate exhibits a shape which corresponds to the lower portion of the first fin plate 11 of the heat sink. Reference numeral 16 designates the holes through which the fasteners 13 of the first and second plates of the heat sink are inserted. Of course, these holes 16 are aligned with similar holes in the first fin plates 11 of the heat sink 10.

According to the present invention, each of said first and second plates 11, 12 exhibits on one side at least a protrusion 17 and on the opposite side at least a recess 18. The protrusion 17 and the recess 18 are made by a stamping operation on the first and second plates 11, 12. Each protrusion 17 on one side of said first plates 11 engages with a positive fit into a corresponding recess 18 on a side of said second plates 12 facing the one side of s-aid first plates 11. In a similar way, each protrusion 17 on one side of said second plates 12 engages with a positive fit into a corresponding recess 18 on a side of said first plates 11 facing the one side of said second plates 12. The protrusion 17 on one side and the recess 18 on the other side of said first and second plates 11, 12 are disposed out of alignment relative to a straight line X in the plane of said plates intersecting the axis of the holes 16, and the axis of the fasteners 13 inserted into said holes, respectively.

With the features of the invention, a relative rotation of the first and second plates 11, 12 in the plane thereof during the assembling of the heat sink is prevented, and therefore the flat surface 15 of the base portion 14 of the heat sink, intended to be connected to the hot side of the thermoelectric module, is not deformed and remains flat.

This ensures that the connection with the hot side of the thermoelectric module has the lowest possible thermal resistance.

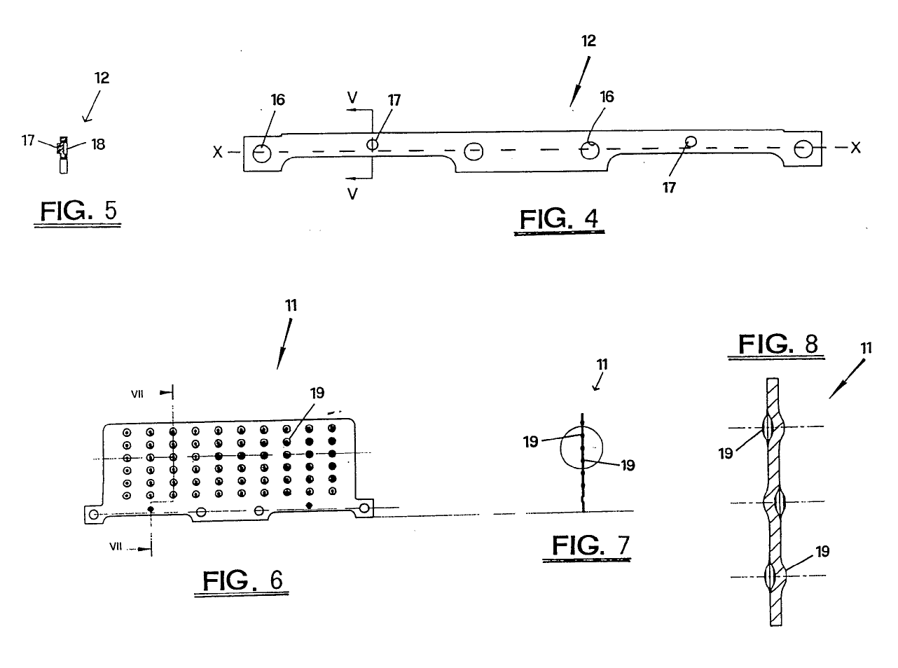

With reference now to FIGS. 6 to 8 of the drawings, there is shown a variant of the first fin plate 11 of the heat sink 10. According to this variant, the opposite sides of the fin plate 11 exhibit a series of alternately disposed bulges 19 made by stamping the plate. These bulges 19 have the purpose of improving the convective eat transfer with the air flowing along the plate.

From the foregoing, it is understood that the invention solves the technical problem of improving the mechanical stability of the heat sink. Of course, the Figures of the drawings show an illustrative embodiment of the invention and various small modifications and changes can be made thereto without departing from the scope of the accompanying claims.

1. A heat sink (10), particularly for a thermoelectric module, of the kind formed of a plurality of first fin plates (11) and second spacer plates (12), alternately disposed side by side and in contact with one another, and comprising fastening members (13) which extend through the first and second plates for fastening one to the other, characterised in that:
each of said first and second plates (11,12) has on one side at least a protrusion (17) and on the opposite side at least a recess (18),
the protrusion (17) on one side of said first and second plates (11,12) engaging into the recess (18) on the facing side of said second and first plates (12,11) respectively, with a positive fit, and
the protrusion (17) on one side and the recess (18) on the opposite side of said first and second plates (11,12) are disposed out of alignment relative to a straight line (X) on the plane of the plates intersecting the axis of the fastening members (13).

2. Heat sink according to claim 1, characterised in that the opposite sides of the fin plates (11) exhibit a series of alternately disposed bulges 19 for improving the convective heat transfer with the air flowing along the said plates
